(19) United States
(12) Patent Application Publication
(10) Pub. No.: US 2012/0286409 A1
(43) Pub. Date: Nov. 15, 2012

(54) UTILIZING A JUMPER CHIP IN PACKAGES WITH LONG BONDING WIRES

(76) Inventors: Jitesh Shah, Fremont, CA (US); Rey Torcuato, San Jose, CA (US)

(21) Appl. No.: 13/104,191

(22) Filed: May 10, 2011

(51) Int. Cl. H01L 23/495; H01L 21/60

(52) U.S. Cl. 257/676; 438/107; 438/123; 257/E23.031; 257/E21.506

(57) ABSTRACT

A combination for electrically connecting an integrated circuit (14) to a lead frame package (18) comprises a first jumper chip (16) and a plurality of bonding wires (20) including at least a first bonding wire and a second bonding wire. The first bonding wire extends between and electrically connects the first jumper chip (16) and the lead frame package (18). Additionally, the second bonding wire extends between and electrically connects the first jumper chip (16) and the integrated circuit (14). The plurality of bonding wires (20) can further include a third bonding wire that extends between and electrically connects the integrated circuit (14) and the lead frame package (18). Further, the combination can also comprise a second jumper chip (216B), and the plurality of bonding wires (20) can further include a third bonding wire and a fourth bonding wire. The third bonding wire can extend between and electrically connect the second jumper chip (216B) and the lead frame package (18). Additionally, the fourth bonding wire can extend between and electrically connect the second jumper chip (216B) and the integrated circuit (14).

### BACKGROUND

Digital systems often include one or more integrated circuits (also referred to as “chips” or “dies”) that are coupled to one or more substrates, such as printed circuit boards, using one or more packages, such as lead frame packages. The printed circuit board provides power to the integrated circuits. The lead frame package includes a plurality of leads, i.e. a plurality of power conductors and a plurality of ground conductors, to electrically connect the integrated circuits to the printed circuit board.

Due to recent advances in microelectronics technology, integrated circuits now occupy less space while performing more functions. For assembling such integrated circuits in a lead frame package, the pads on the chip can be connected to the package leads via a process commonly referred to as wire bonding. Bonding wires of gold, copper or sometimes aluminum are typically used to connect the pads on the chip to the package leads. Due to assembly limitations, attempts are made to restrict the wire lengths so as to not exceed a certain desired maximum length. The length restriction is to avoid wire sweep and other defects, and to otherwise enable the assembly of a reliable package. Unfortunately, in typical lead frame packages, situations sometimes arise where having excessively long wires cannot be avoided. For example, in certain situations, a small integrated circuit is assembled in a larger lead frame package such that bonding wires that exceed the desired maximum length are necessary in order to provide the required electrical connection between the integrated circuit and the printed circuit board.

### SUMMARY

The present invention is directed to a combination for electrically connecting an integrated circuit to a lead frame package. In various embodiments, the combination comprises a first jumper chip and a plurality of bonding wires including at least a first bonding wire and a second bonding wire. The first bonding wire extends between and electrically connects the first jumper chip and the lead frame package. Additionally, the second bonding wire extends between and electrically connects the first jumper chip and the integrated circuit.

In some embodiments, the plurality of bonding wires further includes a third bonding wire that extends between and electrically connects the integrated circuit and the lead frame package.

Additionally, in certain embodiments, the plurality of bonding wires further includes a third bonding wire and a fourth bonding wire. In one such embodiment, the third bonding wire extends between and electrically connects the first jumper chip and the lead frame package. Moreover, in one embodiment, the fourth bonding wire extends between and electrically connects the first jumper chip and the integrated circuit.

Further, in some embodiments, the combination further comprises a second jumper chip, and the plurality of bonding wires further includes a third bonding wire and a fourth bonding wire. In one such embodiment, the third bonding wire extends between and electrically connects the second jumper chip and the lead frame package. Moreover, in one embodiment, the fourth bonding wire extends between and electrically connects the second jumper chip and the integrated circuit.

Still further, the combination can further comprise a third jumper chip, and the plurality of bonding wires can further include a fifth bonding wire and a sixth bonding wire. In such embodiment, the fifth bonding wire extends between and electrically connects the third jumper chip and the lead frame package. Moreover, the sixth bonding wire extends between and electrically connects the third jumper chip and the integrated circuit.

Yet further, the combination can further comprise a fourth jumper chip, and the plurality of bonding wires can further include a seventh bonding wire and an eighth bonding wire. In such embodiment, the seventh bonding wire extends between and electrically connects the fourth jumper chip and the lead frame package. Moreover, the eighth bonding wire extends between and electrically connects the fourth jumper chip and the integrated circuit.

Additionally, the present invention is also directed to a package assembly comprising a lead frame package, an integrated circuit and the combination as described above for electrically connecting the integrated circuit to the lead frame package. The present invention is further directed to a digital system including a printed circuit board and the package assembly as described above that is coupled to the printed circuit board.

Moreover, the present invention is further directed to a combination for electrically connecting a first integrated circuit and a second integrated circuit to a lead frame package; a method for electrically connecting an integrated circuit to a lead frame package; a method for forming a digital system including the steps of electrically connecting a lead frame package to a printed circuit board and electrically connecting an integrated circuit to the lead frame package with the method as describe above; a method for electrically connecting a first integrated circuit and a second integrated circuit to a lead frame package; and a method for forming a digital system including the steps of electrically connecting a lead frame package to a printed circuit board and electrically connecting a first integrated circuit and a second integrated circuit to the lead frame package with the method as described above.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1A is a simplified side view of an embodiment of a digital system including a package assembly having features of the present invention;

FIG. 1B is a top view of the package assembly illustrated in FIG. 1A;

FIG. 1C is a perspective view of an embodiment of the jumper chip usable as part of the digital system illustrated in FIG. 1A;

FIG. 2 is a top view of another embodiment of a package assembly having features of the present invention;

FIG. 3 is a top view of still another embodiment of a package assembly having features of the present invention; and

FIG. 4 is a top view of yet another embodiment of a package assembly having features of the present invention.

### DESCRIPTION

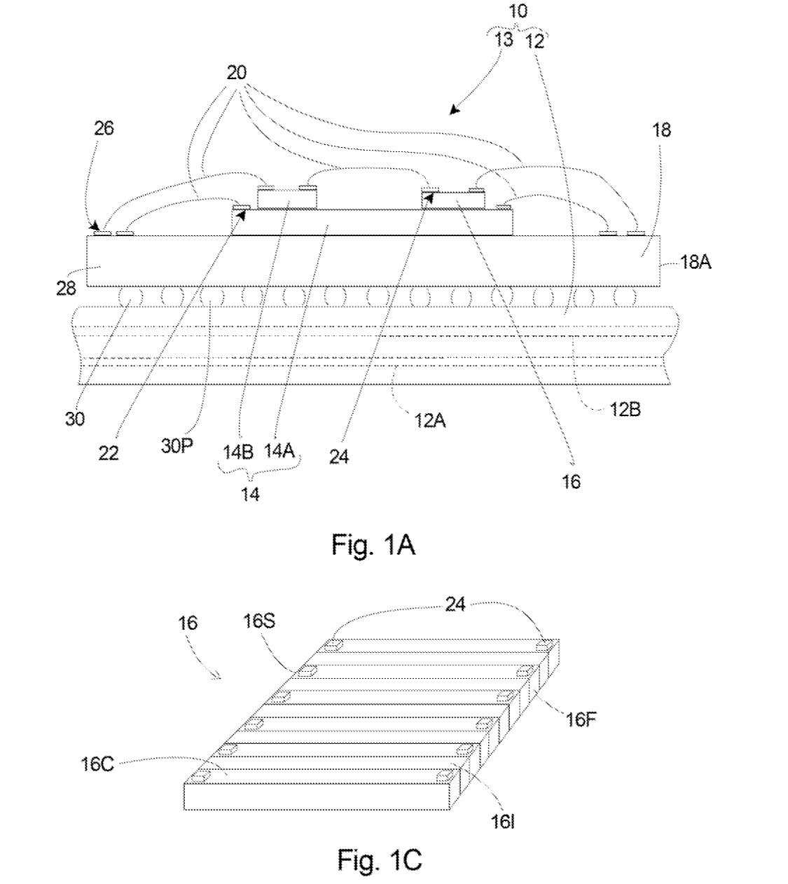

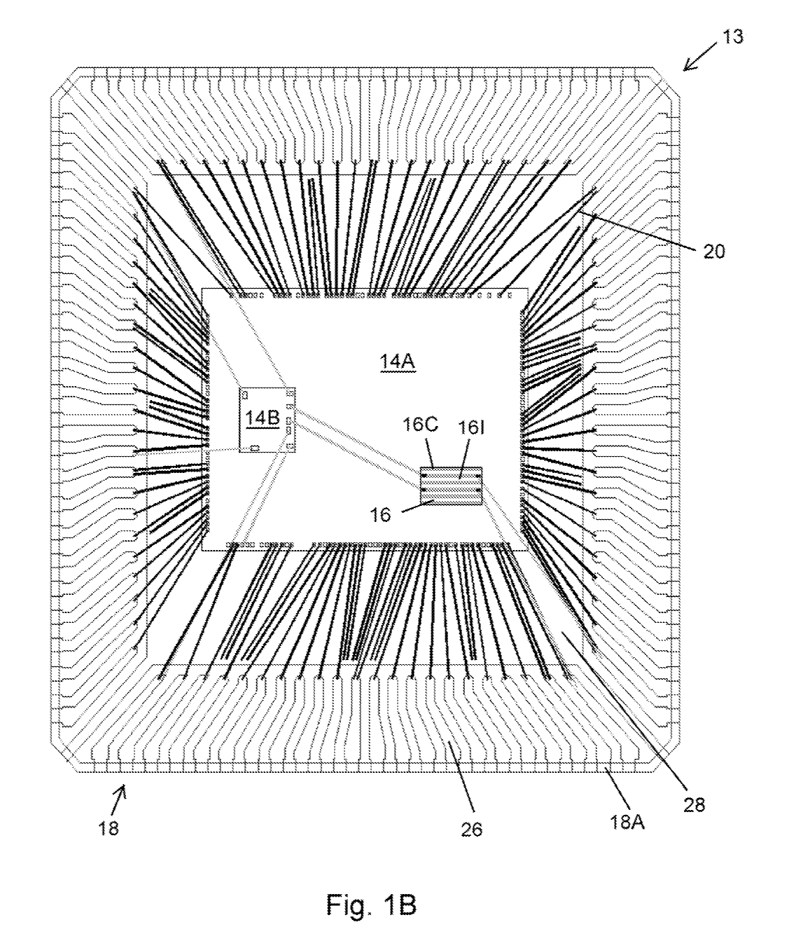

FIG. 1A is a simplified side view of an embodiment of a digital system 10 having features of the present invention. In particular, in the embodiment illustrated in FIG. 1A, the digital system 10 includes a printed circuit board 12 and a package assembly 13 that is coupled to the printed circuit board 12. Additionally, in this embodiment, the package assembly 13 includes one or more integrated circuits 14, a jumper chip 16, and a lead frame package 18 (also referred to herein as a “package”) that utilizes a plurality of bonding wires 20 to attach and electrically connect the one or more integrated circuits 14 and the jumper chip 16 to the printed circuit board 12. The design of each of these components can vary pursuant to the teachings provided herein. Further, in certain alternative embodiments, the digital system 10, i.e. the package assembly 13, can include more than one jumper chip.

As an overview, the digital system 10, i.e. the package assembly 13, is uniquely designed to provide electrical connection to the integrated circuits 14 without the need for bonding wires 20 that exceed a certain desired maximum length. In particular, the digital system 10 utilizes the jumper chip 16 as an intermediate electrical transmission station or bridge that enables the use of a plurality of shorter bonding wires 20, i.e. between the package 18 and the jumper chip 16 and between the jumper chip 16 and the integrated circuits 14, in place of one or more longer bonding wires that would extend between the package 18 and the integrated circuits 14 and that may otherwise exceed the certain desired maximum length. With this design, wire sweep and other related defects can be inhibited and a more reliable package can be assembled. Additionally, the use of the jumper chip 16 enables the connection of the integrated circuits 14 to a lead frame package 18 that may otherwise be too large, i.e. that may otherwise require bonding wires 20 that would exceed the certain desired maximum length.

The printed circuit board 12 includes a flat board that is made of non-conducting material (e.g. an insulating material), and a plurality of predefined conductive metal pathways that are printed on the surface of the board. In one embodiment, the printed circuit board 12 also includes power rail 12A (illustrated in phantom) and a ground rail 12B (illustrated in phantom).

Each of the one or more integrated circuits 14 consists of a number of circuit elements positioned on a chip of silicon crystal or other semiconductor material. The design of each integrated circuit 14 can vary. For example, each integrated circuit 14 can be a wire bond type chip, and/or one or more of the integrated circuits 14 can be a flip type chip. The number of integrated circuits 14 positioned on the package 18 can vary. In this embodiment, the one or more integrated circuits 14 include two integrated circuits, i.e., a first integrated circuit 14A and a second integrated circuit 14B, that are electrically and mechanically connected to the lead frame package 18. Each of the integrated circuits 14 includes a plurality of circuit die pads 22 that enable the integrated circuits 14 to be electrically and mechanically attached to the lead frame package 18A with the plurality of bonding wires 20.

Additionally, as illustrated in this embodiment, the integrated circuits 14 can be arranged in a stacked die configuration, with the first integrated circuit 14A being positioned on top of and/or adjacent to the lead frame package 18, and with the second integrated circuit 14B being positioned on top of and/or adjacent to the first integrated circuit 14A. Further, in the embodiment illustrated in FIG. 1A, the second integrated circuit 14B is substantially smaller than the first integrated circuit 14A, although the relative sizes of the first integrated circuit 14A and the second integrated circuit 14B can be different than those illustrated. Alternatively, in some embodiments, the one or more integrated circuits 14 can include more than two integrated circuits that are arranged in a stacked die configuration or in some other configuration. In such embodiments, one or more of the integrated circuits 14 can be approximately the same size and/or one or more of the integrated circuits 14 can be different sizes. Still alternatively, in certain embodiments, the one or more integrated circuits 14 can include just a single integrated circuit.

It should be noted that the use of the terms “first integrated circuit” and “second integrated circuit” is merely for purposes of simplicity and ease of discussion, and either integrated circuit can be equally referred to as the first integrated circuit or the second integrated circuit.

In an embodiment such as illustrated in FIG. 1A, the one or more integrated circuits 14 and the package 18 cooperate to form a multi-chip package that can have an increased processing capacity as compared to a single chip package. For example, in one embodiment, the multi-chip package can have twice the processing capacity or more, depending upon the number of integrated circuits 14 and the processing capacity of each individual integrated circuit 14.

As described herein, the jumper chip 16 is a unique device which can be maintained in inventory and then used as needed when the application justifies it. In particular, the jumper chip 16 provides an intermediate electrical transmission station or bridge through which at least a portion of the electrical connection between the package 18 and the second integrated circuit 14B can be established. More specifically, the jumper chip 16 includes a silicon substrate having a plurality of spaced apart conductor segments 16C (illustrated in FIG. 1B), or transmission lines, and a plurality of spaced apart insulator segments 16I (illustrated in FIG. 1B). As illustrated, the conduct segments 16C and the insulator segments 16I are positioned relative to one another so that they effectively alternate from one side of the jumper chip 16 to the other, with an insulator segment 16I being positioned between each pair of conductor segments 16C. Additionally, each of the conductor segments 16C or transmission lines extends from one end of the jumper chip 16 to the other. Further, each end of each conductor segment 16C includes a jumper die pad 24 for enabling a bonding wire 20 to be attached at or near each end of the jumper chip 16. With this design, the electrical connections between the package 18 and the integrated circuits 14 can be routed through the jumper chip 16 via the bonding wires 20 such that the digital system 10 can employ bonding wires 20 that do not exceed the desired maximum length. Moreover, as noted above, the package assembly 13 can employ the use of more than one jumper chip 16 to the extent necessary to maintain the bonding wires 20 at or below the desired maximum length. As stated above, limiting the length of the bonding wires 20 can inhibit wire sweep and other defects, and can otherwise enable the assembly of a reliable package.

The lead frame package 18 electrically connects the integrated circuits 14 to the printed circuit board 12. In certain embodiments, the package 18 also fixedly secures the integrated circuits 14 to the printed circuit board 12 and provides mechanical support to the integrated circuits 14. The design of the package 18 can vary. For example, in FIG. 1A, the lead frame package 18 is designed to electrically connect a wire bond type chip to the printed circuit board 12. Alternatively, the package 18 could be designed to electrically connect one or more flip type chips to the printed circuit board 12.

As illustrated in FIG. 1A, the lead frame package 18 includes a lead frame 18A (illustrated more clearly in FIG. 1B) having a plurality of leads 26, a package substrate 28, and a pinout 30.

The plurality of leads 26 are electrically connected, i.e. via the plurality of bonding wires 20, to the integrated circuits 14. In certain embodiments, the plurality of leads 26 can include a plurality of power conductors and a plurality of ground conductors that are connected to the power rail 12A and the ground rail 12B, respectively, of the printed circuit board 12.

The package substrate 28 provides a substantially flat planar surface upon which the integrated circuits 14 are supported relative to the printed circuit board 12. Additionally, the package substrate is positioned substantially within the lead frame 18A.

The pinout 30 electrically and mechanically connects the package substrate 28 to the printed circuit board 12. In one non-exclusive example, the pinout 30 can include a ball grid array (BGA) that electrically and mechanically couples the package 18 to the printed circuit board 12. For example, the pinout 30 can include a plurality of pins 30P. In one non-exclusive embodiment, the pins 30P are solder balls. Further, the pins 30P can include negative pins, positive pins and/or signal pins. These pins 30P can be strategically arranged to reduce crosstalk and/or to improve signal timing margins.

The plurality of bonding wires 20 electrically and mechanically connects the one or more integrated circuits 14 to the package 18. The design and positioning of the plurality of bonding wires 20 can vary pursuant to the teachings provided herein. In FIG. 1A, a majority of the bonding wires 20 are positioned on top of and adjacent to the package substrate 28. In particular, as illustrated, the bonding wires 20 are positioned to provide electrical connection and extend between the leads 26 and the integrated circuits 14, and provide electrical connection and extend between the leads 26 and the jumper chip 16. Further, as illustrated in FIG. 1A, at least one bonding wire 20 provides electrical connection and extends between the jumper chip 16 and the second integrated circuit 14B.

In some embodiments, the bonding wires 20 can be formed from a gold or copper material. Alternatively, in some embodiments, the bonding wires 20 can be formed from an aluminum material.

In certain embodiments, the digital system 10 can further include a capacitor assembly (not illustrated) that stabilizes the voltage delivered to the one or more integrated circuits 14 by providing power to the one or more integrated circuits 14 during high frequency current transients. The design and location of the capacitor assembly can vary. In certain embodiments, the capacitor assembly is physically very close to the one or more integrated circuits 14 and has a relatively low impedance path to the one or more integrated circuits 14.

FIG. 1B is a top view of the package assembly 13 illustrated in FIG. 1A. In particular, FIG. 1B illustrates more clearly the design and relative positioning of the lead frame 18A, the first integrated circuit 14A, the second integrated circuit 14B and the jumper chip 16.

In this embodiment, the lead frame 18A is substantially square shaped and the plurality of leads 26 are arranged about the perimeter of the lead frame 18A. Additionally, an equal number of leads 26 are positioned along each side of the lead frame 18A. Alternatively, the lead frame 18A can have a different shape and/or the leads 26 can be positioned in a different manner about the lead frame 18A.

As illustrated in FIG. 1B, the first integrated circuit 14A can be substantially centrally positioned on top of the package substrate 28. Additionally, as illustrated in FIG. 1B, the second integrated circuit 14B can be centrally positioned on top of and along one side of the first integrated circuit 14A. Further, as illustrated in this embodiment, the jumper chip 16 is positioned on top of and toward one corner of the first integrated circuit 14A. With this design, (i) at least one of the plurality of bonding wires 20 extends between and electrically connects the package 18, i.e. the leads 26, and the first integrated circuit 14A; (ii) at least one of the plurality of bonding wires 20 extends between and electrically connects the package 18 and the second integrated circuit 14B; (iii) at least one of the plurality of bonding wires 20 extends between and electrically connects the package 18 and the jumper chip 16; and (iv) at least one of the plurality of bonding wires 20 extends between and electrically connects the jumper chip 16 and the second integrated circuit 14B. Alternatively, the second integrated circuit 14B can have a different positioning relative to the first integrated circuit 14A.

FIG. 1C is a perspective view of an embodiment of the jumper chip 16 usable as part of the digital system 10 illustrated in FIG. 1A. In particular, as illustrated and as noted above, the jumper chip 16 includes a silicon substrate having the plurality of spaced apart conductor segments 16C, or transmission lines, and the plurality of spaced apart insulator segments 16I. In this embodiment, the jumper chip 16 includes six conduct segments 16C and five insulator segments 16I that are positioned relative to one another so that they effectively alternate from one side of the jumper chip 16 to the other. Additionally, as illustrated, one of the insulator segments 16I is positioned between each pair of conductor segments 16C. Alternatively, the jumper chip 16 can include greater than or less than six conductor segments 16C and/or greater than or less than five insulator segments 16I. Still alternatively, the conductor segments 16C and the insulator segments 16I can have a different positioning relative to one another.

Additionally, each of the conductor segments 16C or transmission lines extends substantially from a first end 16F of the jumper chip 16 to a second end 16S of the jumper chip 16. Further, each conductor segment 16C includes a jumper die pad 24 that is positioned substantially adjacent to the first end 16F of the jumper chip 16 and another jumper die pad 24 that is positioned substantially adjacent to the second end 16S of the jumper chip 16. The jumper die pads 24 enable a bonding wire 20 (illustrated in FIG. 1A) to be attached at or near each end 16F, 16S of the jumper chip 16. With this design, the electrical connections between the package 18 (illustrated in FIG. 1A) and the integrated circuits 14 (illustrated in FIG. 1A) can be routed through the jumper chip 16 via the bonding wires 20 such that the digital system 10 can employ bonding wires 20 that do not exceed the desired maximum length. During use, a first bonding wire 20 can extend between and electrically connect a lead 26 (illustrated in FIG. 1B) to the jumper die pad 24 of one of the conductor segments 16C at or near the first end 16F of the jumper chip 16; the electrical connection can continue through that same conductor segment 16C or transmission line from the first side 16F to the second side 16S of the jumper chip; and a second bonding wire 20 can extend between and electrically connect the jumper die pad 24 of that same conductor segment 16C at or near the second end 16S of the jumper chip 16 to one of the circuit die pads 22 (illustrated in FIG. 1A) on one of the integrated circuits 14 (illustrated in FIG. 1A). Accordingly, the digital system 10 can be designed so as to inhibit wire sweep and other defects that may be present if the digital system employs bonding wires 20 that do exceed the desired maximum length.

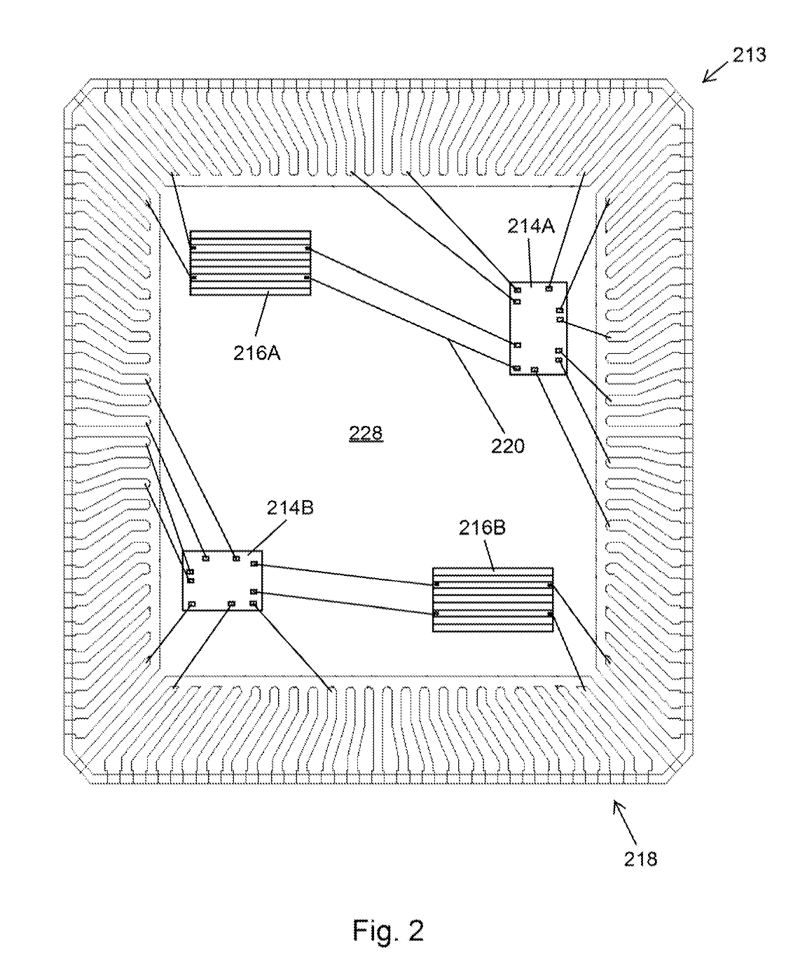

FIG. 2 is a top view of another embodiment of a package assembly 213 having features of the present invention. In this embodiment, the package assembly 213 includes a plurality of integrated circuits, i.e. a first integrated circuit 214A and a second integrated circuit 214B; a plurality of jumper chips, i.e. a first jumper chip 216A and a second jumper chip 216B; and a lead frame package 218 that utilizes a plurality of bonding wires 220 to attach and electrically connect the integrated circuits 214A, 214B and the jumper chips 216A, 216B to the printed circuit board 12 (illustrated in FIG. 1A).

It should be noted that the use of the terms “first jumper chip” and “second jumper chip” is also merely for purposes of simplicity and ease of discussion, and either jumper chip can be equally referred to as the first jumper chip or the second jumper chip.

The design of the integrated circuits 214A, 214B, the jumper chips 216A, 216B, and the lead frame package 218 is substantially similar to the design of the integrated circuits 14A, 14B, the jumper chip 16, and the lead frame package 18, respectively, illustrated and described above in relation to FIG. 1A. Accordingly, the design of these features will not be described in detail herein.

As illustrated in FIG. 2, the first integrated circuit 214A can be positioned on top of and toward one corner of the package substrate 228; the second integrated circuit 214B can be positioned laterally spaced apart from the first integrated circuit 14A on top of and toward another corner of the package substrate 228; the first jumper chip 216A can be positioned on top of and toward still another corner of the package substrate 228; and the second jumper chip 216B can be positioned on top of and toward yet another corner of the package substrate 228. With this design, (i) at least one of the plurality of bonding wires 220 extends between and electrically connects the package 218 and the first integrated circuit 214A; (ii) at least one of the plurality of bonding wires 220 extends between and electrically connects the package 218 and the second integrated circuit 214B; (iii) at least one of the plurality of bonding wires 220 extends between and electrically connects the package 218 and the first jumper chip 216A; (iv) at least one of the plurality of bonding wires 220 extends between and electrically connects the first jumper chip 216A and the first integrated circuit 214A; (v) at least one of the plurality of bonding wires 220 extends between and electrically connects the package 218 and the second jumper chip 216B; and (vi) at least one of the plurality of bonding wires 220 extends between and electrically connects the second jumper chip 216B and the second integrated circuit 214B.

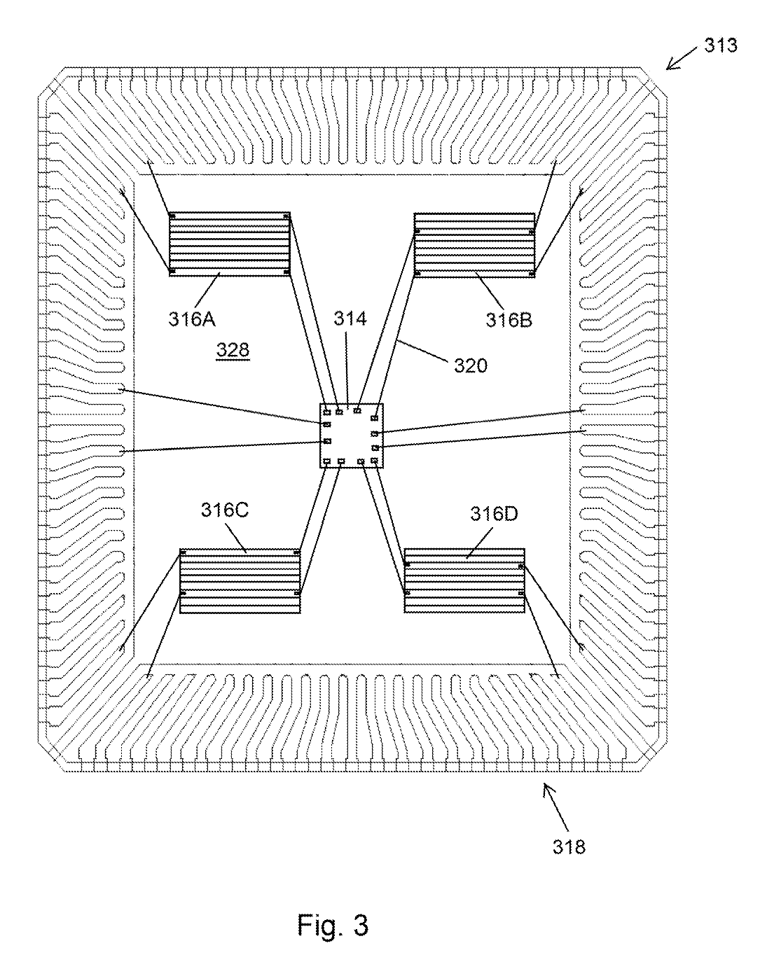

FIG. 3 is a top view of still another embodiment of a package assembly 313 having features of the present invention. In this embodiment, the package assembly 313 includes an integrated circuit 314; a plurality of jumper chips, i.e. a first jumper chip 316A, a second jumper chip 316B, a third jumper chip 316C and a fourth jumper chip 316D; and a lead frame package 318 that utilizes a plurality of bonding wires 320 to attach and electrically connect the integrated circuit 314 and the jumper chips 316A-D to the printed circuit board 12 (illustrated in FIG. 1A).

The design of the integrated circuit 314, the jumper chips 316A-D, and the lead frame package 318 is substantially similar to the design of the integrated circuits 14A, 14B, the jumper chip 16, and the lead frame package 18, respectively, illustrated and described above in relation to FIG. 1A. Accordingly, the design of these features will not be described in detail herein.

As illustrated in FIG. 3, the integrated circuit 314 can be substantially centrally positioned on top of the package substrate 328. Further, as illustrated in this embodiment, the jumper chips 316A-D can be positioned about the integrated circuit 314 such that each jumper chip 316A-D is positioned on top of and toward a different corner of the package substrate 328. With this design, (i) at least one of the plurality of bonding wires 320 extends between and electrically connects the package 318 and the integrated circuit 314; (ii) at least one of the plurality of bonding wires 320 extends between and electrically connects the package 318 and the first jumper chip 316A; (iii) at least one of the plurality of bonding wires 320 extends between and electrically connects the first jumper chip 316A and the integrated circuit 314; (iv) at least one of the plurality of bonding wires 320 extends between and electrically connects the package 318 and the second jumper chip 316B; (v) at least one of the plurality of bonding wires 320 extends between and electrically connects the second jumper chip 316B and the integrated circuit 314; (vi) at least one of the plurality of bonding wires 320 extends between and electrically connects the package 318 and the third jumper chip 316C; (vii) at least one of the plurality of bonding wires 320 extends between and electrically connects the third jumper chip 316C and the integrated circuit 314; (viii) at least one of the plurality of bonding wires 320 extends between and electrically connects the package 318 and the fourth jumper chip 316D; and (ix) at least one of the plurality of bonding wires 320 extends between and electrically connects the fourth jumper chip 316D and the integrated circuit 314.

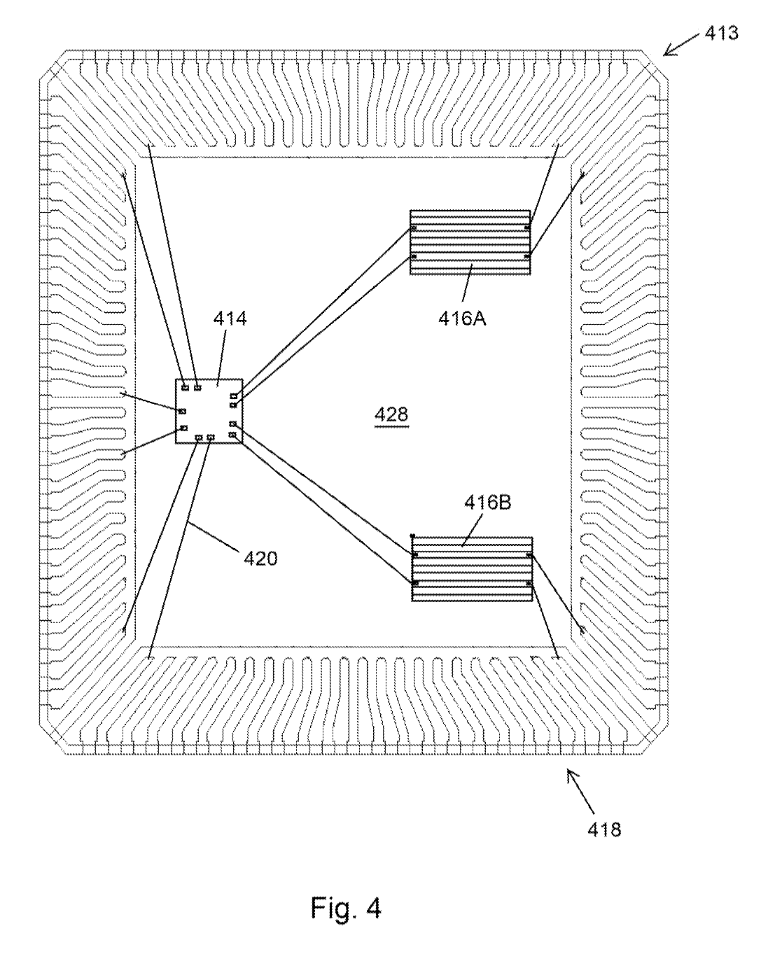

FIG. 4 is a top view of yet another embodiment of a package assembly 413 having features of the present invention. In this embodiment, the package assembly 413 includes an integrated circuit 414; a plurality of jumper chips, i.e. a first jumper chip 416A and a second jumper chip 416B; and a lead frame package 418 that utilizes a plurality of bonding wires 420 to attach and electrically connect the integrated circuit 414 and the jumper chips 416A, 416B to the printed circuit board 12 (illustrated in FIG. 1A).

The design of the integrated circuit 414, the jumper chips 416A, 416B, and the lead frame package 418 is substantially similar to the design of the integrated circuits 14A, 14B, the jumper chip 16, and the lead frame package 18, respectively, illustrated and described above in relation to FIG. 1A. Accordingly, the design of these features will not be described in detail herein.

As illustrated in FIG. 4, the integrated circuit 414 is positioned to one side on top of the package substrate. Further, as illustrated in this embodiment, two jumper chips, i.e. a first jumper chip and a second jumper chip, are positioned about the integrated circuit. With this design, (i) at least one of the plurality of bonding wires 420 extends between and electrically connects the package 418 and the integrated circuit 414; (ii) at least one of the plurality of bonding wires 420 extends between and electrically connects the package 418 and the first jumper chip 416A; (iii) at least one of the plurality of bonding wires 420 extends between and electrically connects the first jumper chip 416A and the integrated circuit 414; (iv) at least one of the plurality of bonding wires 420 extends between and electrically connects the package 418 and the second jumper chip 416B; and (v) at least one of the plurality of bonding wires 420 extends between and electrically connects the second jumper chip 416B and the integrated circuit 414.

While a number of exemplary aspects and embodiments of a package assembly 13 have been discussed above, those of skill in the art will recognize certain modifications, permutations, additions and sub-combinations thereof. It is therefore intended that the following appended claims and claims hereafter introduced are interpreted to include all such modifications, permutations, additions and sub-combinations as are within their true spirit and scope.

What is claimed is:

1. A combination for electrically connecting an integrated circuit to a lead frame package, the combination comprising:
a first jumper chip; and
a plurality of bonding wires including at least a first bonding wire and a second bonding wire, the first bonding wire extending between and electrically connecting the first jumper chip and the lead frame package, and the second bonding wire extending between and electrically connecting the first jumper chip and the integrated circuit.

2. The combination of claim 1 wherein the plurality of bonding wires further includes a third bonding wire that extends between and electrically connects the integrated circuit and the lead frame package.

3. The combination of claim 1 wherein the plurality of bonding wires further includes a third bonding wire and a fourth bonding wire, the third bonding wire extending between and electrically connecting the first jumper chip and the lead frame package, and the fourth bonding wire extending between and electrically connecting the first jumper chip and the integrated circuit.

4. The combination of claim 1 further comprising a second jumper chip, wherein the plurality of bonding wires further includes a third bonding wire and a fourth bonding wire, the third bonding wire extending between and electrically connecting the second jumper chip and the lead frame package, and the fourth bonding wire extending between and electrically connecting the second jumper chip and the integrated circuit.

5. The combination of claim 4 further comprising a third jumper chip, wherein the plurality of bonding wires further includes a fifth bonding wire and a sixth bonding wire, the fifth bonding wire extending between and electrically connecting the third jumper chip and the lead frame package, and the sixth bonding wire extending between and electrically connecting the third jumper chip and the integrated circuit.

6. The combination of claim 5 further comprising a fourth jumper chip, wherein the plurality of bonding wires further includes a seventh bonding wire and an eighth bonding wire, the seventh bonding wire extending between and electrically connecting the fourth jumper chip and the lead frame package, and the eighth bonding wire extending between and electrically connecting the fourth jumper chip and the integrated circuit.

7. A package assembly comprising a lead frame package, an integrated circuit and the combination of claim 1 for electrically connecting the integrated circuit to the lead frame package.

8. A digital system including a printed circuit board and the package assembly of claim 7 that is coupled to the printed circuit board.

9. A combination for electrically connecting a first integrated circuit and a second integrated circuit to a lead frame package, the combination comprising:
a first jumper chip; and
a plurality of bonding wires including at least a first bonding wire, a second bonding wire and a third bonding wire, the first bonding wire extending between and electrically connecting the first jumper chip and the lead frame package, the second bonding wire extending between and electrically connecting the first jumper chip and the first integrated circuit, and the third bonding wire extending between and electrically connecting the second integrated circuit to the lead frame package.

10. The combination of claim 9 wherein the plurality of bonding wires further includes a fourth bonding wire that extends between and electrically connects the first integrated circuit and the lead frame package.

11. The combination of claim 9 wherein the first integrated circuit is mounted substantially on top of the second integrated circuit.

12. The combination of claim 9 wherein the second integrated circuit is positioned laterally spaced apart from the first integrated circuit.

13. The combination of claim 12 wherein the plurality of bonding wires further includes a fourth bonding wire and a fifth bonding wire, the fourth bonding wire extending between and electrically connecting the first jumper chip and the lead frame package, and the fifth bonding wire extending between and electrically connecting the first jumper chip and the second integrated circuit.

14. The combination of claim 9 further comprising a second jumper chip, the plurality of bonding wires further includes a fourth bonding wire and a fifth bonding wire, the fourth bonding wire extending between and electrically connecting the second jumper chip and the lead frame package, and the fifth bonding wire extending between and electrically connecting the second jumper chip and the second integrated circuit.

15. A package assembly comprising a lead frame package, a first integrated circuit, a second integrated circuit and the combination of claim 9 for electrically connecting the first integrated circuit and the second integrated circuit to the lead frame package.

16. A digital system including a printed circuit board and the package assembly of claim 15 that is coupled to the printed circuit board.

17. A method for electrically connecting an integrated circuit to a lead frame package, the method comprising the steps of:
electrically connecting a first jumper chip and the lead frame package with a first bonding wire that extends between the first jumper chip and the lead frame package; and
electrically connecting the first jumper chip and the integrated circuit with a second bonding wire that extends between the first jumper chip and the integrated circuit.

18. The method of claim 17 further comprising the step of electrically connecting the integrated circuit and the lead frame package with a third bonding wire that extends between the integrated circuit and the lead frame package.

19. The method of claim 17 further comprising the steps of electrically connecting a second jumper chip and the lead frame package with a third bonding wire that extends between the second jumper chip and the lead frame package; and electrically connecting the second jumper chip and the integrated circuit with a fourth bonding wire that extends between the second jumper chip and the integrated circuit.

20. A method for forming a digital system including the steps of electrically connecting a lead frame package to a printed circuit board and electrically connecting an integrated circuit to the lead frame package with the method of claim 17.

21. A method for electrically connecting a first integrated circuit and a second integrated circuit to a lead frame package, the method comprising the steps of:
electrically connecting a first jumper chip and the lead frame package with a first bonding wire that extends between the first jumper chip and the lead frame package;
electrically connecting the first jumper chip and the first integrated circuit with a second bonding wire that extends between the first jumper chip and the first integrated circuit; and
electrically connecting the second integrated circuit and the lead frame package with a third bonding wire that extends between the second integrated circuit and the lead frame package.

22. The method of claim 21 further comprising the step of electrically connecting the first integrated circuit and the lead frame package with a fourth bonding wire that extends between the first integrated circuit and the lead frame package.

23. The method of claim 14 further comprising the steps of electrically connecting the first jumper chip and the lead frame package with a fourth bonding wire that extends between the first jumper chip and the lead frame package, and electrically connecting the first jumper chip and the second integrated circuit with a fifth bonding wire that extends between the first jumper chip and the second integrated circuit.

24. The method of claim 14 further comprising the steps of electrically connecting a second jumper chip and the lead frame package with a fourth bonding wire that extends between the second jumper chip and the lead frame package, and electrically connecting the second jumper chip and the second integrated circuit with a fifth bonding wire that extends between the second jumper chip and the second integrated circuit.

25. A method for forming a digital system including the steps of electrically connecting a lead frame package to a printed circuit board and electrically connecting a first integrated circuit and a second integrated circuit to the lead frame package with the method of claim 21.
